(19) United States
(12) Patent Application Publication
(10) Pub. No.: US 2023/0107206 A1
(43) Pub. Date: Apr. 6, 2023

(54) DECORATIVE VAPOR DEPOSITION SHEET

(71) Applicant: 3M INNOVATIVE PROPERTIES COMPANY, St. Paul, MN (US)

(72) Inventors: Masami Miura, Yamagata (JP); Guy M. Kallman, Woodbury, MN (US)

(21) Appl. No.: 17/801,385

(22) PCT Filed: Feb. 23, 2021
(86) PCT No.: PCT/IB2021/051516

§ 371 Date: Aug. 22, 2022

(30) Foreign Application Priority Data
Feb. 27, 2020 (JP) 2020-032179

(51) Int. Cl. B32B 7/12; B32B 27/30; B32B 27/40; B32B 33/00; B32B 37/10

(52) U.S. Cl. CPC B32B 7/12; B32B 27/304; B32B 27/308; B32B 27/40; B32B 33/00; B32B 37/1018; B32B 2255/10; B32B 2255/205; B32B 2250/02; B32B 2311/16; B32B 2327/12; B32B 2333/12; B32B 2375/00

(57) ABSTRACT

Object: Provided is a decorative vapor deposition sheet that can reduce or prevent a defect, such as the breaking of a metal vapor deposition layer or the entire sheet, even when applied to a forming method requiring high temperature or the like. The decorative vapor deposition sheet of an embodiment of the present disclosure is a decorative vapor deposition sheet including a cover resin layer and a metal vapor deposition layer, in which the cover resin layer has a thickness of approximately 50 micrometers or greater, the metal vapor deposition layer exhibits a granular structure, a breaking elongation of the decorative vapor deposition sheet at 20° C. is approximately 120% or greater, and a breaking elongation of the decorative vapor deposition sheet at 160° C. is approximately 350% or greater.

### TECHNICAL FIELD

The present disclosure relates to a decorative vapor deposition sheet.

### BACKGROUND ART

In recent years, various metal vapor deposition sheets have been developed and used in a wide range of fields, such as interior products or exterior products.

Patent Document 1 (WO 2015/050011) describes a decorative vapor deposition film including a tin vapor deposition film on a polymer film, the tin vapor deposition film being configured such that one or both of the surface portion of the tin vapor deposition film and the interface portion with the polymer film are turned into a black layer, and the black layer being formed by turning the tin vapor deposition film into black by allowing oxygen gas to flow into the vicinity of the surface of the polymer film to make the degree of vacuum in a range from 0.8×10⁻² Pa to 5.0×Pa⁻² Pa during the formation of the tin vapor deposition film.

Patent Document 2 (JP 62-174189 A) describes an insulating transfer raw material formed by sequentially laminating a release layer, a protective layer, a metal vapor deposition layer, and an adhesive layer on one side of a substrate, in which the metal vapor deposition layer is formed in an island structure to impart insulating properties.

Patent Document 3 (JP 3198079 U) describes a three-dimensional molded signboard obtained by adhering a resin-moldable transparent metal vapor deposition film to a transparent color acrylic plate and three-dimensionally forming.

### CITATION LIST

### Patent Literature

Patent Document 1: WO 2015/050011

Patent Document 2: JP 62-174189 A

Patent Document 3: JP 3198079 U

### SUMMARY OF INVENTION

### Technical Problem

A technique known in the art molds a resin plate using a method, such as vacuum forming, to obtain a three-dimensional molded article, such as a signboard. The vacuum forming method typically requires highly bending a thick resin plate at least partially, and thus high temperature conditions, such as, for example, exceeding 100° C., can be applied.

Typically, a metal vapor deposition sheet that can exhibit metal-like decorativeness has been often used by adhering the sheet to a low bending molded article, such as a curved face, prepared in advance. In such a case, a defect, such as breaking of the metal vapor deposition layer or the entire sheet, is less likely to occur. However, when a resin plate to which a metal vapor deposition sheet is adhered is applied to a forming method, such as a vacuum forming method in which, for example, severe conditions exceeding 100° C. are applied, the defect as described above has been more likely to occur compared with the use of a metal vapor deposition sheet adhered to a molded article.

The present disclosure provides a decorative vapor deposition sheet that can reduce or prevent a defect, such as breaking of the metal vapor deposition layer or the entire sheet, even when applied to a forming method requiring high temperature or the like.

### Solution to Problem

An embodiment of the present disclosure provides a decorative vapor deposition sheet including a cover resin layer and a metal vapor deposition layer, in which the cover resin layer has a thickness of approximately 50 micrometers or greater, the metal vapor deposition layer exhibits a granular structure, a breaking elongation of the decorative vapor deposition sheet at 20° C. is approximately 120% or greater, and a breaking elongation of the decorative vapor deposition sheet at 160° C. is approximately 350% or greater.

Another embodiment of the present disclosure provides an article in which the decorative vapor deposition sheet described above is adhered to a substrate.

Still another embodiment of the present disclosure provides a method of producing an article having a three-dimensional shape, the method including vacuum-forming after applying the decorative vapor deposition sheet described above to a substrate.

### Advantageous Effects of Invention

The present disclosure can provide a decorative vapor deposition sheet that can reduce or prevent a defect, such as breaking of the metal vapor deposition layer or the entire sheet, even when applied to a forming method requiring high temperature or the like.

The above description should not be construed as disclosing all embodiments of the present invention and all advantages relating to the present invention.

### BRIEF DESCRIPTION OF DRAWINGS

FIG. 1A is a schematic cross-sectional view of an article in which a decorative vapor deposition sheet according to an embodiment of the present disclosure is applied to a substrate, and FIG. 1B is a schematic cross-sectional view of an article in which a decorative vapor deposition sheet according to another embodiment of the present disclosure is applied to a substrate.

FIG. 2 is a scanning electron micrograph of a metal vapor deposition layer having a granular structure of an embodiment of the present disclosure.

### DESCRIPTION OF EMBODIMENTS

Hereinafter, the present invention will be described in more detail with reference to the drawings for the purpose of illustrating representative embodiments of the present invention, but the present invention is not limited to these embodiments. Regarding the reference numbers in the drawings, constituents labeled with similar numbers across different drawings are similar or corresponding constituents.

In the present disclosure, a “sheet” encompasses an article referred to as a “film”.

In the present disclosure, “on”, for example, in “the metal vapor deposition layer is disposed on the adhesive layer” is intended that the metal vapor deposition layer is disposed directly on the upper side of the adhesive layer, or that the metal vapor deposition layer is indirectly disposed on the upper side of the adhesive layer via another layer.

In the present disclosure, “under”, for example, in “the metal vapor deposition layer is disposed under the cover resin layer” is intended that the metal vapor deposition layer is disposed directly at the lower side of the cover resin layer, or that the metal vapor deposition layer is indirectly disposed at the lower side of the cover resin layer via another layer.

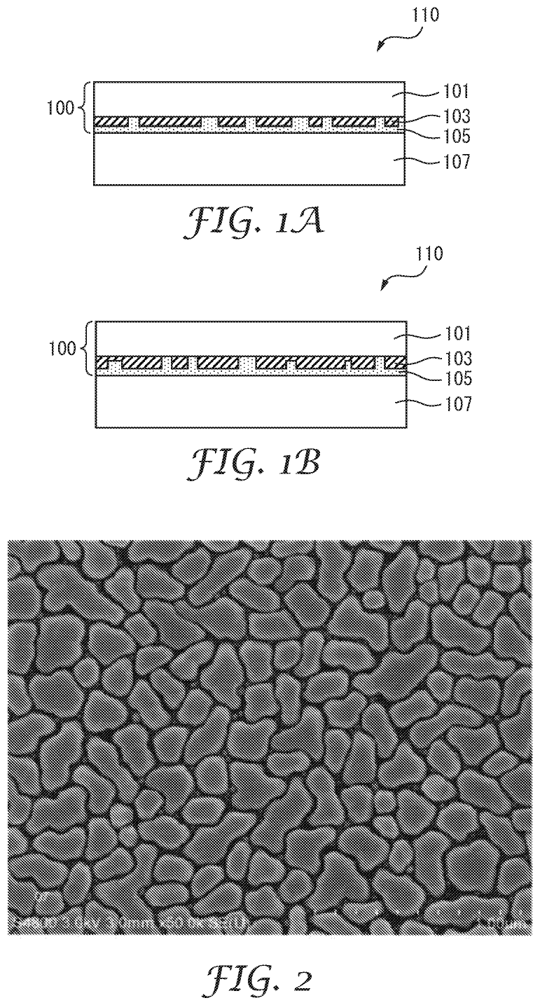

In the present disclosure, a “granular structure” is intended to be a structure in which, for example, in observing a surface of a metal vapor deposition layer directly or indirectly through a cover resin layer or the like with a scanning electron microscope or an optical microscope, the surface portion of at least one side of the metal vapor deposition layer exhibits a discontinuous state as illustrated in FIG. 2 and appears to be granular. Here, the “discontinuous state” means that at least the surface portion of the metal vapor deposition layer is to be regularly or randomly discontinuous, and a cross-sectional portion in the thickness direction of the metal vapor deposition layer is not limited to being entirely in a discontinuous configuration, but the surface portion of the metal vapor deposition layer, the surface portion on the opposite side of the surface portion in a discontinuous state, may be entirely or partially in a continuous configuration. That is, in the present disclosure, the “metal vapor deposition layer exhibiting a granular structure” is not limited to a configuration as illustrated in FIG. 1A in which the entire metal vapor deposition layer is discontinuous and can also encompass such a configuration as illustrated in FIG. 1B in which the surface portion of the metal vapor deposition layer on one side is partially continuous.

In the present disclosure, a “three-dimensional shape” is intended to be a three-dimensional shape in which the Z axis is added to a two-dimensional shape (a planar shape with only the X axis and the Y axis).

In the present disclosure, “substantially” means that a variation caused by a manufacturing error or the like is included, and is intended to allow a variation of approximately ±20%.

In the present disclosure, “transparent” refers to an average transmittance in the visible light region (wavelength of 400 nm to 700 nm) measured in accordance with JIS K 7375 of approximately 80% or higher, and the average transmittance may be desirably approximately 85% or higher or approximately 90% or higher. The upper limit of the average transmittance is not particularly limited, but it can be specified that the upper limit is, for example, lower than approximately 100%, approximately 99% or lower, or approximately 98% or lower.

In the present disclosure, “translucent” refers to an average transmittance in the visible light region (wavelength of 400 nm to 700 nm) measured in accordance with JIS K 7375 of lower than approximately 80%, and the average transmittance may be desirably approximately 75% or lower, and is intended not to completely hide an underlying layer.

In the present disclosure, “(meth)acrylic” means acrylic or methacrylic.

Hereinafter, a decorative vapor deposition sheet of the present disclosure will be described with reference to the drawings.

A decorative vapor deposition sheet 100 in FIGS. 1A and 1B includes a cover resin layer 101, a metal vapor deposition layer 103, and an adhesive layer 105. Here, the adhesive layer 105 is an optional constituent layer, and the decorative vapor deposition sheet of the present disclosure need not necessarily include such a layer.

Hereinafter, for the purpose of illustrating representative embodiments of the present disclosure, details of each component will be described with some reference signs omitted.

The cover resin layer of the present disclosure has a thickness of approximately 50 micrometers or greater. The cover resin layer is, for example, a layer that can be applied to cover at least the metal vapor deposition layer, in applying the decorative vapor deposition sheet to a substrate, such as a polycarbonate plate. This cover resin layer with a certain thickness can contribute to reducing or preventing a defect, such as breaking of the metal vapor deposition layer or the entire sheet, during molding processing.

For example, in highly bending the substrate to which the decorative vapor deposition sheet is applied using a vacuum forming method, a stress, such as a pressure, may be applied locally to the bent portion in a state where high temperature conditions exceeding 100° C. are applied. The cover resin layer of the present disclosure is thick compared with the thickness of a surface protective coating layer or the like applied to a decorative vapor deposition sheet known in the art. Thus, even if a stress is locally applied under such high temperature conditions, the decorative vapor deposition sheet of the present disclosure including such a cover resin layer can stretch without tearing the cover resin layer at the portion where the stress is applied and can reduce or prevent a defect, such as breaking of the metal vapor deposition layer or the entire sheet.

In some embodiments, the decorative vapor deposition sheet of the present disclosure is subjected to molding processing in a state of being applied to a substrate (e.g., a polycarbonate plate) via the adhesive layer. During the molding processing, when a stress is locally applied under high temperature conditions, the adhesive layer is also stretched in addition to the cover resin layer. The resin layer thinner than the cover resin layer of the present disclosure is susceptible to the influence of the stretching movement of the adhesive layer and may trap air during molding processing to cause air entrapment (bubbling). The cover resin layer of the present disclosure with a certain thickness is less susceptible to the stretching movement of the adhesive layer and thus can also contribute to reducing or preventing the occurrence of such air entrapment.

The thickness of the cover resin layer is not particularly limited as long as the thickness is approximately 50 micrometers or greater, but in terms of performance of preventing breaking or the like, the performance of preventing air entrapment, or the like, the thickness of the cover resin layer can be, for example, approximately 60 micrometers or greater, approximately 70 micrometers or greater, or approximately 80 micrometers or greater. The upper limit of the thickness of the cover resin layer is not particularly limited, but in terms of molding processability, manufacturing cost, and the like, the thickness can be, for example, approximately 200 micrometers or less, approximately 150 micrometers or less, approximately 100 micrometers or less, or approximately 90 micrometers or less. Here, the thickness of each layer in the decorative vapor deposition sheet in the laminate configuration can be defined as an average value of thicknesses of at least any five locations in a target layer of the laminate configuration, for example, a cover resin layer, the thicknesses being measured in the thickness direction of the laminate configuration using a scanning electron microscope or an optical microscope.

The resin raw material for the cover resin layer is not particularly limited, and for example, at least one selected from urethane, polyvinylidene fluoride, and (meth)acrylic can be employed. Among them, urethane and polyvinylidene fluoride are preferred in terms of anticorrosive effect, curl resistance, outgas resistance, and the like of the metal vapor deposition layer, and in addition, urethane is more preferred in terms of transparency after bending. The principle of the excellent outgas resistance of the cover resin layer containing urethane and/or polyvinylidene fluoride is uncertain, but it is believed that the cover resin layer containing these resins has superior gas permeation performance compared with a cover resin layer constituted of another resin and can transmit gas generated from a substrate, such as polycarbonate, and thus can reduce or prevent a defect, such as air entrapment (bubbling) caused by the generated gas. The cover resin layer obtained using such a raw material may have a single layer configuration or may have a laminate configuration. Examples of the cover resin layer in a laminate configuration include a layer composed of polyvinylidene fluoride (PVDF), a layer composed of polymethylmethacrylate (PMMA), or layers having two or more layers containing different ratios of PVDF and PMMA.

The cover resin layer is typically preferably transparent, but in order to provide an intended appearance, the cover resin layer may be entirely or partially transparent, translucent, or opaque in the visible range.

To improve adhesive properties with the metal vapor deposition layer or the like, the cover resin layer may be subjected to surface treatment, such as corona treatment or plasma treatment, on the surface.

The metal vapor deposition layer of the present disclosure is a layer that exhibits a granular structure and can exhibit decorative performance commonly referred to as metal-like or metallic. In the metal vapor deposition layer of the present disclosure, in observing the surface of the metal vapor deposition layer directly or indirectly through the cover resin layer or the like with a scanning electron microscope or an optical microscope, the surface portion of at least one side of the metal vapor deposition layer exhibits a discontinuous state as illustrated in FIG. 2. As a result, for example, an internally illuminated signboard or sign obtained using a decorative vapor deposition sheet including such a metal vapor deposition layer can transmit light from a light source, such as an LED, from inside and can exhibit the metal-like or metallic decorative performance also at night.

The optical transmission performance of such a metal vapor deposition layer can be evaluated, for example, by optical density (OD value) according to the test method described below. The optical density of the metal vapor deposition layer, for example, can be approximately 1.0 or greater, approximately 1.1 or greater, or approximately 1.2 or greater, and can be approximately 1.9 or less, approximately 1.8 or less, or approximately 1.7 or less. The decorative vapor deposition sheet including the metal vapor deposition layer having an optical density in such a range can transmit light from an internal light source when used, for example, in an internally illuminated signboard or a sign and thus can well exhibit the metal-like or metallic decorative performance also at night.

The metal vapor deposition layer of the present disclosure exhibits such a granular structure, and thus when the metal vapor deposition layer is stretched by, for example, vacuum forming, the force is more likely to propagate between the granular portions as illustrated in FIG. 2 rather than acting to break or fracture the granular portions themselves that exhibit the metal-like or metallic decorativeness. As a result, the decorative vapor deposition sheet including the metal vapor deposition layer of the present disclosure can exhibit good metal-like or metallic decorative performance even when highly stretched.

In observing the cross-sectional portion in the thickness direction, the metal vapor deposition layer of the present disclosure may have a configuration in which the layer is entirely discontinuous as illustrated in FIG. 1A or may have a configuration in which the surface portion of the metal vapor deposition layer, the surface portion on the opposite side of the surface portion in a discontinuous state, may be entirely or partially in a continuous state as illustrated in FIG. 1B. Even if the metal vapor deposition layer has a configuration in which the surface portion on one side of the metal vapor deposition layer is in a continuous state, the continuous metal vapor deposition portion located between the granular portions typically has a thickness thinner than the thickness of the granular portion, and thus the metal vapor deposition layer can exhibit the optical transmission performance as described above.

In some embodiments, in terms of outgas resistance, that is, reducing or preventing a defect, such as air entrapment caused by gas generated from the substrate to which the decorative vapor deposition sheet is applied, the metal vapor deposition layer preferably has a configuration in which the layer is partially or entirely discontinuous in observing the cross-sectional portion in the thickness direction.

Whether the metal vapor deposition layer is partially or entirely in a discontinuous configuration can be evaluated by observing the cross-sectional portion in the thickness direction of the metal vapor deposition layer with a scanning electron microscope or an optical microscope. On the other hand, the metal vapor deposition layer in such a discontinuous configuration has poor conductivity compared with the metal vapor deposition layer in a continuous configuration, and thus whether the metal vapor deposition layer is partially or entirely in a discontinuous configuration can be indirectly evaluated by measuring the surface resistance value of the metal vapor deposition layer. The surface resistance value of the metal vapor deposition layer partially or entirely in a discontinuous configuration can be, for example, approximately 8.0×10¹⁰ Ω/□ or greater, approximately 9.0×10¹⁰ Ω/□ or greater, or approximately 10×10¹⁰ Ω/□ or greater. Here, the unit of the surface resistance value may be described as “Ω per square”, “ohms per square”, “Ω/sq.”, or “ohms/sq.” in place of “Ω/□”.

The size and shape of the granular portion and the distance between the granular portions in the metal vapor deposition layer surface as illustrated in FIG. 2, and the thickness of the metal vapor deposition layer, and the like are not particularly limited, and can be appropriately selected in consideration of, for example, required performance (e.g., decorativeness, such as metal-like appearance; optical transparency; or outgas resistance) according to the intended use and by adjusting the vapor deposition rate, the deposition time, the vapor deposition raw material, and the like.

The raw material for the metal vapor deposition layer is not particularly limited, and examples of the raw material include aluminum, nickel, gold, silver, copper, platinum, chronium, iron, tin, indium, titanium, lead, zinc, and germanium. These materials can be used alone or in combination of two or more. Among them, indium and/or tin are preferred in terms of ease of forming the granular structure and the like, and in addition, indium is more preferred in terms of waterproofing.

The decorative vapor deposition sheet of the present disclosure includes the cover resin layer with a thickness of approximately 50 micrometers or greater and the metal vapor deposition layer that exhibits a granular structure and thus can reduce or prevent a defect, such as breaking of the metal vapor deposition layer or the entire sheet even when applied to a forming method requiring high temperature, for example, exceeding 100° C., or the like. Such performance can be evaluated, for example, by the breaking elongation according to the test method described below or the stretch test.

In some embodiments, the decorative vapor deposition sheet of the present disclosure can achieve a breaking elongation at 20° C. of, for example, approximately 120% or greater, approximately 125% or greater, or approximately 130% or greater. The decorative vapor deposition sheet of the present disclosure has good elongation properties not only under high temperature but also at room temperature of approximately 20° C. and thus can reduce or prevent air trapping in work to adhere the sheet to a substrate, such as a polycarbonate plate. The upper limit of the breaking elongation is not particularly limited but can be, for example, approximately 200% or less, approximately 190% or less, or approximately 180% or less.

In some embodiments, the decorative vapor deposition sheet of the present disclosure can achieve a breaking elongation at 160° C. of, for example, approximately 350% or greater, approximately 355% or greater, or approximately 360% or greater. The upper limit of the breaking elongation is not particularly limited but can be, for example, approximately 500% or less, approximately 480% or less, or approximately 450% or less.

In some embodiments, the decorative vapor deposition sheet of the present disclosure can exhibit a “good” result, that is, a state in which no apparent breaking or crack occurs in the metal vapor deposition layer in visual observation in the stretch test described below. Here, the “apparent breaking or crack in the metal vapor deposition layer” is intended to be breaking or a crack in the granular portion contributing to the metallic luster. For example, the thickness of the connecting portion between the granular portions as illustrated in FIG. 1B is typically significantly small compared with the thickness of the granular portion, and breaking or a crack in such a connecting portion is unlikely to affect the metallic luster and cannot be visually observed. Thus the “apparent breaking or crack in the metal vapor deposition layer” does not encompass breaking or a crack in such a connecting portion.

In some embodiments, the decorative vapor deposition sheet of the present disclosure can exhibit excellent metallic luster also after being highly stretched. For example, in forming an article, such as a signboard, by a vacuum forming method, the decorative vapor deposition sheet may be highly bent. In a typical vapor deposition sheet, the metal vapor deposition layer is highly stretched in such a bent portion, and a defect, such as a crack, is prone to occur in such a bent portion, thus likely reducing the metallic luster. The decorative vapor deposition sheet of the present disclosure has the specific cover resin layer and the specific metal vapor deposition layer in combination. Thus, it is believed that even when the decorative vapor deposition sheet is exposed to a high degree of stretching, the cover resin layer prevents the elongation of the metal vapor deposition layer at the stretched portion, as well as the force due to the stretching propagates not in the granular portion contributing to the metallic luster but between the granular portions, and thus the decorative vapor deposition sheet can exhibit good metallic luster. Such performance can be evaluated by reflectance after stretching according to the test method described below. The decorative vapor deposition sheet of the present disclosure can achieve a reflectance, for example, at an area magnification of 300% in stretching the sheet 1.5 times each in the longitudinal and lateral directions of approximately 20% or greater, approximately 23% or greater, or approximately 25% or greater. The upper limit of such a reflectance is not particularly limited but can be, for example, approximately 50% or less, approximately 45% or less, approximately 40% or less, or approximately 35%.

In some embodiments, the decorative vapor deposition sheet of the present disclosure may further include an additional layer as an optional component, such as a decorative layer other than the metal vapor deposition layer, a bonding layer (which may be referred to as a “primer layer” or the like) for bonding the constituent layers, an adhesive layer, and a release liner for protecting the adhesive layer, in a range that does not inhibit the effect of the present disclosure. These layers can be employed alone or in combination of two or more.

In some embodiments, the decorative vapor deposition sheet of the present disclosure can have a decorative layer disposed, for example, on or under the cover resin layer. The decorative layer may be entirely or partially transparent, translucent, or opaque in the visible range and can be applied, for example, to the entire surface or part of the cover resin layer.

Examples of the decorative layer include, but are not limited to, a color layer that exhibits a paint color, for example, a light color, such as white and yellow, and a strong color, such as red, brown, green, blue, gray, and black; a pattern layer that imparts a design pattern (such as a wood grain, a stone grain, a geometric pattern, or a leather pattern), a logo, a picture pattern, or the like to an article; a relief (embossed pattern) layer in which recesses and protrusions are provided on the surface; and combinations of these layers.

The raw material for the color layer is not limited to the following, but for example, a raw material obtained by dispersing a pigment in a binder resin, such as a (meth)acrylic resin or a polyurethane resin, can be used, the pigment being, such as an inorganic pigment (such as carbon black, chrome yellow, yellow iron oxide, colcothar, or red iron oxide); or an organic pigment, such as a phthalocyanine pigment (such as phthalocyanine blue or phthalocyanine green), an azo lake pigment, an indigo pigment, a perinone pigment, a perylene pigment, a quinophthalone pigment, a dioxazine pigment, or a quinacridone pigment (such as quinacridone red).

The color layer can be formed using such a raw material, for example, by a coating method, such as gravure coating, roll coating, die coating, bar coating, or knife coating or can be also formed by a printing method, such as inkjet printing.

The pattern layer is not limited to the following, but for example, a cover resin layer or the like having a pattern, such as a design pattern, a logo, or a picture pattern, directly applied using a printing method, such as gravure direct printing, gravure offset printing, inkjet printing, laser printing, or screen printing, may be employed, or a film, a sheet, or the like having a design pattern, a logo, a picture pattern, or the like formed by coating, such as gravure coating, roll coating, die coating, bar coating, or knife coating; punching; etching; or the like can be also used. For example, a raw material similar to those used in the color layer can be used for the pattern layer.

For the relief layer, a thermoplastic resin film having a concavo-convex shape on the surface may be used, the concavo-convex shape being obtained by a well-known method in the art, such as, for example, emboss finishing, scratch processing, laser processing, dry etching processing, or hot press processing. The relief layer can be also formed by coating a thermosetting or radiation-curable resin, such as a curable (meth)acrylic resin, on a release liner having a concavo-convex shape, curing the resin by heat or radiation, and removing the release liner.

The thermoplastic resin, thermosetting resin, and radiation-curable resin used in the relief layer are not particularly limited, but for example, a fluororesin; a polyester resin, such as PET or PEN; a (meth)acrylic resin; a polyolefin resin, such as polyethylene or polypropylene; a thermoplastic elastomer; a polycarbonate resin; a polyamide resin; an ABS resin; an acrylonitrile-styrene resin; a polystyrene resin, a vinyl chloride resin, or a polyurethane resin may be used. The relief layer may contain at least one of the pigments used in the color layer.

The thickness of the decorative layer is to be appropriately adjusted according to the required decorativeness or the like and not particularly limited but, for example, can be approximately 1 micrometers or greater, approximately 3 micrometers or greater, or approximately 5 micrometers or greater, and can be approximately 30 micrometers or less, approximately 20 micrometers or less, or approximately 15 micrometers or less.

In some embodiments, to bond each constituting layer, the decorative vapor deposition sheet of the present disclosure can include a bonding layer. For the bonding layer, for example, a typically used adhesive can be used, such as a solvent, emulsion, pressure-sensitive, heat-sensitive, thermosetting, or ultraviolet-curable adhesive of (meth)acrylic, polyolefin, polyurethane, polyester, or rubber. The bonding layer can be applied by a well-known coating method or the like.

The thickness of the bonding layer, for example, can be approximately 0.05 micrometers or greater, approximately 0.5 micrometers or greater, or approximately 5 micrometers or greater, and can be approximately 30 micrometers or less, approximately 20 micrometers or less, or approximately 10 micrometers or less.

In some embodiments, the decorative vapor deposition sheet may further include an adhesive layer for adhering the decorative vapor deposition sheet to a substrate, which is an adherend and described below. As illustrated in FIGS. 1A and 1B, the adhesive layer is preferably disposed under the metal vapor deposition layer 103 disposed under the cover resin layer 101.

A raw material similar to those for the bonding layer can be used for the bonding layer, but the raw material is preferably a (meth)acrylic pressure-sensitive adhesive (tacky adhesive) in terms of moldability, penetration into the granular structure of the metal vapor deposition layer, outgas resistance, or the like. The adhesive layer may be applied to the adherend rather than the decorative vapor deposition sheet.

The thickness of the adhesive layer is not limited to the following but, for example, can be approximately 5 micrometers or greater, approximately 10 micrometers or greater, or approximately 20 micrometers or greater, and can be approximately 100 micrometers or less, approximately 80 micrometers or less, or approximately 50 micrometers or less. Here, as illustrated in FIGS. 1A and 1B, a portion of the adhesive layer can penetrate into the granular structure of the metal vapor deposition layer 103, but the thickness of the adhesive layer in the present disclosure is intended to be the distance from the bottommost portion of the metal vapor deposition layer 103 to the substrate 107 according to FIGS. 1A and 1B.

Raw materials that can be used to form the cover resin layer, the decorative layer, the bonding layer, the adhesive layer, or an additional optional layer described above can contain, as an optional component, a filler, a reinforcing member, an antioxidant, a UV absorbent, a photostabilizer, a thermal stabilizer, a tackifier, a crosslinking agent, a curing agent, a thickener, a dispersant, a plasticizer, a flow enhancer, a surfactant, a leveling agent, an anticorrosive agent, a silane coupling agent, a catalyst, a pigment, or a dye, in a range that does not inhibit the effect of the present disclosure. These components can be used alone, or in combination of two or more. For example, the use of a thickener can contribute to a thick coating of the cover resin layer.

In some embodiments, to protect the adhesive layer, an optional preferred release liner can be used. Representative examples of the release liner include those prepared from paper (e.g., kraft paper) or a polymer raw material (e.g., polyolefin, such as polyethylene or polypropylene; ethylene vinyl acetate; polyurethane; or polyester, such as polyethylene terephthalate). The release liner may be applied as necessary with a layer of a release agent, such as a silicone-containing raw material or a fluorocarbon-containing raw material.

The thickness of the release liner, for example, can be approximately 5 micrometers or greater, approximately 15 micrometers or greater, or approximately 25 micrometers or greater, and can be approximately 300 micrometers or less, approximately 200 micrometers or less, or approximately 150 micrometers or less. The thickness of the release liner can be defined as an average value calculated from at least five measurements of thickness at any portion of the release liner after removing from the adhesive layer, the measurements being made using High-Accuracy Digimatic Micrometer (MDH-25 MB, available from Mitutoyo Corporation).

Each layer other than the metal vapor deposition layer of the decorative vapor deposition sheet of the present disclosure can be appropriately prepared by a well-known method, for example, a printing method, such as gravure direct printing, gravure offset printing, inkjet printing, or screen printing; or a coating method, such as gravure coating, roll coating, die coating, bar coating, knife coating, or extrusion coating; a lamination method; or a transfer method. One of these methods is used alone or a plurality of them is used in combination.

A method of producing the metal vapor deposition layer of the present disclosure is not particularly limited as long as the metal vapor deposition layer can exhibit the granular structure, and a well-known vapor deposition method can be employed, such as, for example, a vacuum deposition method, an ion plating method, or a chemical vapor deposition method, but a vacuum deposition method is preferred in terms of formability and the like of the granular structure.

A production method is described below as an example, but the method of producing the decorative vapor deposition sheet is not limited to this method. For example, for the decorative vapor deposition sheet configured to include the cover resin layer, the metal vapor deposition layer, the adhesive layer, and the release liner described above, a cover resin composition is coated on the release liner, a drying step as necessary and a curing step are applied to form the cover resin layer, and then the metal vapor deposition layer is deposited on the cover resin layer. An adhesive is coated on the resulting metal vapor deposition layer, the adhesive layer is formed by applying as necessary a drying step or a curing step, and the decorative vapor deposition sheet can be prepared. Here, the cover resin layer formed into a film or sheet in advance may be used.

An embodiment of the present disclosure can provide an article in which the decorative vapor deposition sheet described above is adhered to a substrate. Examples of such an article may include a substantially flat article prior to molding processing, the substantially flat article being formed by adhering the decorative vapor deposition sheet to a substrate, such as a polycarbonate plate; or an article having a three-dimensional shape obtained by further molding such a substantially flat article; or an article obtained by adhering the decorative vapor deposition sheet to a substrate having a shape, such as a curved face. The decorative vapor deposition sheet of the present disclosure, even when applied to a forming method requiring high temperature or the like, for example, a vacuum forming, such as vacuum pressure forming, can reduce or prevent a defect, such as breaking of the metal vapor deposition layer or the entire sheet and thus is advantageous to use for an article having a three-dimensional shape obtained by further molding a substantially flat article. Here, “high temperature” in the present disclosure, for example, can be intended to be approximately 100° C. or higher, higher than approximately 100° C., approximately 120° C. or higher, or approximately 150° C. or higher, and can be intended to be approximately 250° C. or lower, approximately 230° C. or lower, or approximately 200° C. or lower. The pressure applied in the vacuum pressure forming method can be, for example, higher than approximately 3 atm, approximately 4 atm or higher, or approximately 5 atm or higher when the atmospheric pressure is 1 atm. The upper limit of the pressure is not particularly limited but can be, for example, approximately 20 atm or lower, approximately 15 atm or lower, or approximately 10 atm or lower.

In the present disclosure, the “three-dimensional shape” is typically intended to be a three-dimensional shape in which the Z axis is added to a two-dimensional shape (a planar shape with only the X axis and the Y axis) but can be intended to be a three-dimensional shape having a highly bent portion among such three-dimensional shapes. Here, in the present disclosure, the “highly bent portion” can be intended that in an article, for example, an internally illuminated signboard, either of an angle of the bent portion visually identified from the side where the illumination of the cover portion of the internally illuminated signboards is placed in the cover portion or an angle of the bent portion visually identified from the outside of the cover portion is approximately 140 degrees or less, approximately 130 degrees or less, approximately 120 degrees or less, approximately 110 degrees or less, or approximately 100 degrees or less, and approximately 50 degrees or greater, approximately 60 degrees or greater, approximately 70 degrees or greater, approximately 80 degrees or greater, approximately 90 degrees or greater, or greater than approximately 90 degrees.

The raw material for the substrate is not particularly limited, and, for example, glycol-modified polyethylene terephthalate (PET-G), (meth)acrylic, polycarbonate, an acrylonitrile-butadiene-styrene copolymer (ABS), or a mixture of these raw materials can be used. (Meth)acrylic substrates or polycarbonate substrates are prone to generate gas during molding processing or during use over time compared with PET-G substrates or the like, and thus they may have caused a defect, such as air entrapment (bubbling) between the substrate and the decorative vapor deposition sheet. Use of the decorative vapor deposition sheet of an embodiment of the present disclosure, for example, the decorative vapor deposition sheet including the cover resin layer containing urethane and/or polyvinylidene fluoride excellent in outgas resistance and the metal vapor deposition layer having a configuration in which the layer is partially or entirely discontinuous in the cross-sectional portion in the thickness direction can contribute to correcting a defect, such as air entrapment and thus can be advantageously used for substrates prone to generate such gas.

The substrate is typically preferably transparent or translucent (e.g., milky white), but to provide an intended appearance, the substrate may be entirely or partially transparent, translucent, or opaque in the visible range.

The thickness of the substrate is not particularly limited and can be, for example, approximately 0.2 mm or greater, approximately 0.5 mm or greater, approximately 1.0 mm or greater, or approximately 1.5 mm or greater, and can be approximately 3.0 mm or less, approximately 2.5 mm or less, or approximately 2.0 mm or less.

In some embodiments, the decorative vapor deposition sheet of the present disclosure can be used for, for example, signboards (e.g., internally illuminated signboards and externally illuminated signboards); signs (e.g., internally illuminated signs and externally illuminated signs); various interior or exterior products, for example, interior or exterior products for vehicles, such as automobiles, railways, aircrafts, and ships (e.g., roof members; pillar members; door trim members; instrument panel members; front members, such as hoods; bumper members; fender members; side sill members; and interior panel members); and building members (e.g., window glasses; doors; window frames; roof members, such as tiles; outer wall members; and wallpapers). In addition, the heat resistant shrinkable adhesive film of the present disclosure can be used for electrical appliances, such as personal computers, smartphones, mobile phones, refrigerators, and air conditioners; stationery; furniture; desks; various containers, such as cans; and the like. Among them, the decorative vapor deposition sheet of the present disclosure is preferably used in signboards or signs and more preferably used in internally illuminated signboards or internally illuminated signs.

The method for molding a substantially flat article into a three-dimensional shape, the substantially flat article being formed by adhering the decorative vapor deposition sheet of the present disclosure to a substrate, is not particularly limited, and a well-known method can be appropriately used. For example, a thermoforming method can be employed, and specifically, examples of the method may include a three-dimensional overlay method (TOM); a vacuum forming method, such as a vacuum pressure forming method; a pressure forming method; and a press forming method. The decorative vapor deposition sheet of the present disclosure, even when applied to a forming method requiring high temperature or the like, can reduce or prevent a defect, such as breaking of the metal vapor deposition layer or the entire sheet, and thus can be applied to a method that has been prone to cause such a defect, for example, a well-known vacuum pressure forming method as a technique of exposing an article to high temperature, and then applying air pressure higher than the atmospheric pressure and vacuuming to obtain a high precision molded article.

### EXAMPLES

In the following examples, specific embodiments of the present disclosure will be illustrated, but the present invention is not limited to these examples. All “parts” and “percent” are based on mass unless otherwise specified.

The raw materials used in the examples are shown in Table 1 below.

TABLE 1

| Trade | | |
|---|---|---|
| designation or | | |
| abbreviation | Description | Available from |
| E UW-5002 | Urethane resin | Ube Industries, Ltd. |
| | | (Minato-ku, Tokyo, Japan) |
| Tinuvin (trade | Photostabilizer | BASF Japan Ltd. (Chuo- |
| name) 292 | | ku, Tokyo, Japan) |
| Tinuvin (trade | UV absorbent | BASF Japan Ltd. (Chuo- |
| name) 1130 | | ku, Tokyo, Japan) |
| V-02 | Crosslinking agent | Nisshinbo Chemical Inc. |
| | | (Chuo-ku, Tokyo, Japan) |
| ACRYSOL | Thickener | Dow Chemical Japan |
| (trade name) | | Limited (Shinagawa-ku, |
| RM-8W | | Tokyo, Japan) |
| Dynol (trade | Leveling agent | Nissin Chemical Co., Ltd. |
| name) 604 | | (Echizen City, Fukui |
| | | Prefecture, Japan) |
| IPA | Isopropyl alcohol | Fuji Film Wako Pure |
| | | Chemical Industries, Ltd. |
| | | (Osaka City, Osaka, Japan) |
| Denka DX | Film with a thickness of | Denka Company Limited |
| Film 14S0250 | approximately 50 μm based | (Chuo-ku, Tokyo, Japan) |
| | on polyvinylidene fluoride | |
| | (PVDF) and alloyed | |
| Release sheet | Sheet including an acrylic | 3M Japan Limited |
| with pressure | pressure-sensitive adhesive | (Shinagawa-ku, |
| sensitive | layer with a thickness of | Tokyo, Japan) |
| adhesive | approximately 30 μm on a | |
| | polyester release liner | |

### Preparation of Decorative Vapor Deposition Sheet

### Example 1

A mixed liquid containing approximately 6.2 parts by mass of Tinuvin (trade name) 292, approximately 10.4 parts by mass of Tinuvin (trade name) 1130, approximately 26.9 parts by mass of V-02, and approximately 56.5 parts by mass of IPA was prepared. The mixed liquid was blended into a solution containing approximately 83.3 parts by mass of E UW-5002, and a cover resin composition containing a urethane resin was prepared. The cover resin composition was then coated on a polyester release liner with a knife coater and dried in an oven at approximately 60° C. for approximately 1 minute, at approximately 90° C. for approximately 1 minute, and at approximately 120° C. for approximately 1 minute, and a cover resin layer with a thickness of approximately 60 micrometers was prepared.

A metal vapor deposition layer constituted of indium in a granular structure was prepared on the film including the cover resin layer by a vacuum vapor deposition method to make the optical density approximately 1.1. Then, a release sheet with a pressure-sensitive adhesive was adhered to the metal vapor deposition layer via an adhesive layer, and a decorative vapor deposition sheet was prepared.

### Example 2

A decorative vapor deposition sheet of Example 2 was prepared in the same manner as in Example 1 with the exception that the thickness of the cover resin layer was changed to approximately 90 micrometers.

### Example 3

A decorative vapor deposition sheet of Example 3 was prepared in the same manner as in Example 1 with the exception that the film including the cover resin layer was changed to a Denka DX Film 14S0250 with a thickness of approximately 50 micrometers.

### Comparative Example 1

A decorative vapor deposition sheet of Comparative Example 1 was prepared in the same manner as in Example 1 with the exception that the thickness of the cover resin layer was changed to approximately 40 micrometers.

### Comparative Example 2

A decorative vapor deposition sheet of Comparative Example 2 was prepared in the same manner as in Example 3 with the exception that the film was changed to a Denka DX Film 14S0250 with a thickness of approximately 30 micrometers.

### Comparative Example 3

A decorative vapor deposition sheet of Comparative Example 3 was prepared in the same manner as in Example 3 with the exception that the metal vapor deposition layer was changed to a vapor deposition layer constituted of aluminum having no granular structure.

### Example 4

A mixed liquid containing approximately 6.2 parts by mass of Tinuvin (trade name) 292, approximately 10.4 parts by mass of Tinuvin (trade name) 1130, approximately 26.9 parts by mass of V-02, and approximately 56.5 parts by mass of IPA was prepared. The mixed liquid was blended into a solution containing approximately 83.3 parts by mass of E UW-5002, approximately 2.0 parts by mass of ACRYSOL (trade name) RM-8W, and approximately 0.5 parts by mass of Dynol (trade name) 604, and a cover resin composition containing a urethane resin was prepared. The cover resin composition was then coated on a polyester release liner with a knife coater and dried in an oven at approximately 60° C. for approximately 1 minute, at approximately 90° C. for approximately 1 minute, and at approximately 120° C. for approximately 1 minute, and a cover resin layer with a thickness of approximately 60 micrometers was prepared.

A metal vapor deposition layer constituted of indium in a granular structure was prepared on the film including the cover resin layer by a vacuum vapor deposition method to make the optical density approximately 1.7. Then, a release sheet with a pressure-sensitive adhesive was adhered to the metal vapor deposition layer via an adhesive layer, and a decorative vapor deposition sheet was prepared.

### Physical Property Evaluation Tests

Properties of the decorative vapor deposition sheet were evaluated using the following methods.

### Evaluation Test of Granular Structure of Metal Vapor Deposition Layer

The surface of the metal vapor deposition layer prior to adhering the adhesive layer was observed at a measurement magnification of 50000× using a scanning electron microscope (S-3400N, available from Hitachi High-Technologies Corporation). The surface of the metal vapor deposition layer exhibiting the granular structure was rated as “present”, and the surface of the metal vapor deposition layer not exhibiting the granular structure was rated as “absent”. The results are shown in Table 2.

### Breaking Elongation Test

The decorative vapor deposition sheet was cut to a size of 25 mm in width and 150 mm in length, and a test sample was prepared. The test sample was attached to a Tensilon Tensile Tester (available from Orientec Co., Ltd.) to make the check area approximately 100 mm in length and pulled at a tensile speed of 300 mm/min in an environment at 20° C. or 160° C., and the value when the test sample broke was measured. The measurement was made five times, and the average values are shown in Table 2.

### Tensile Test

The decorative vapor deposition sheet cut to a size of 100 mm in width and 100 mm in length was adhered to a PET-G film (Peteres (trade name), available from Mitsubishi Chemical Corporation) with a thickness of approximately 100 micrometers, and the test sample was prepared. The test sample was attached to a biaxial stretcher (KARO, available from Itochu Machine-Technos Corporation) and stretched 1.75 times in the length direction and 1.75 times in the width direction in an environment at 160° C. The appearance of the metal vapor deposition layer after stretching was visually observed. The test sample without the occurrence of a crack and/or breaking in the metal vapor deposition layer was rated as “good”, and the test sample with the occurrence of a crack and/or breaking in the metal vapor deposition layer was rated as “bad”. The results are shown in Table 2.

### Optical Density Test

The optical density (OD value) of the metal vapor deposition layer of the decorative vapor deposition sheet prior to adhering the adhesive layer was measured using a Gretag Macbeth D200-II densitometer (available from Sakata Inx Eng. Co., Ltd.). Measurements were made at any five locations of the metal vapor deposition layer, and the average values are shown in Table 2. Here, the metal vapor deposition layer of the decorative vapor deposition sheet of Comparative Example 3 did not have optical transmission performance, and thus the optical density was not measured.

### Surface Resistance Test

The surface resistance value of the metal vapor deposition layer of the decorative vapor deposition sheet prior to adhering the adhesive layer was measured using an MCP-HT800 (available from Mitsubishi Chemical Analytech Co., Ltd.). Measurements were made at any five locations of the metal vapor deposition layer, and the average values are shown in Table 2.

### Reflectance Test After Stretching

The decorative vapor deposition sheet cut to a size of 100 mm in width and 100 mm in length was adhered to a PET-G film (Peteres (trade name), available from Mitsubishi Chemical Corporation) with a thickness of approximately 100 micrometers, and the test sample was prepared. The test sample was attached to a biaxial stretcher (KARO, available from Itochu Machine-Technos Corporation) and stretched 1.5 times in the length direction and 1.5 times in the width direction to make the area magnification 300% in an environment at 160° C. The reflectance of the cover resin layer side at the substantially center portion of the test sample after stretching was measured using a LAMBDA 1050 (available from PerkinElmer Co., Ltd.). The measurement was made five times, and the average values are shown in Table 2. Here, in the metal vapor deposition layers of the decorative vapor deposition sheets of Comparative Examples 1 and 2, a defect, such as a crack, occurred during stretching, and thus the reflectance was not measured.

### Out Gas Resistance Test

The decorative vapor deposition sheet cut to a size of 50 mm in width and 50 mm in length was adhered to a polycarbonate substrate (PC1600, available from Paltek Corporation) or an acrylic substrate (Acrylite (trade name) EX001, available from Mitsubishi Chemical Corporation) with a thickness of approximately 5 millimeters, and the test sample was prepared. The resulting test sample was allowed to stand in an oven at 65° C. for 24 hours, and then the appearance of the test sample was visually observed. The test sample without the occurrence of air entrapment (bubbling) of 2 mm or greater in the maximum length was rated as “good”, and the test sample with the occurrence of air entrapment (bubbling) of 2 mm or greater in the maximum length was rated as “bad”. The results are shown in Table 2. Here, in Table 2, “PC substrate” is intended to be the “polycarbonate substrate”, and “AC substrate” is intended to be the “acrylic substrate”.

TABLE 2

| | Film thickness | | Breaking | | | | Surface | Reflectance | Outgas resistance | |
|---|---|---|---|---|---|---|---|---|---|---|
| | (μm) of cover | Granular | elongation (%) | | Tensile | Optical | resistance | (%) after | PC | AC |
| | resin layer | structure | 20° C. | 160° C. | test | density | value (Ω/□) | stretching | substrate | substrate |
| Example 1 | 60 | Present | 132 | 350 | Good | 1.1 | >10 × 10¹⁰ | 28 | Good | Good |
| Example 2 | 90 | Present | 183 | 412 | Good | 1.1 | >10 × 10¹⁰ | 25 | Good | Good |
| Example 3 | 50 | Present | 126 | 367 | Good | 1.1 | >10 × 10¹⁰ | 21 | Good | Good |
| Comparative | 40 | Present | 120 | 323 | Bad | 1.1 | >10 × 10¹⁰ | Not | Good | Good |
| Example 1 | | | | | (breaking) | | | measured | | |
| Comparative | 30 | Present | 110 | 304 | Not | 1.1 | >10 × 10¹⁰ | Not | Good | Good |
| Example 2 | | | | | measured | | | measured | | |
| Comparative | 50 | Absent | 118 | 326 | Bad | — | 8.71 × 10⁹ | 31 | Bad | Bad |
| Example 3 | | | | | (crack) | | | | | |
| Example 4 | 60 | Present | 135 | 362 | Good | 1.7 | >10 × 10¹⁰ | 28 | Good | Good |

Various variations of the above embodiments and examples will be apparent to those skilled in the art without departing from the basic principle of the present invention. In addition, various modifications and variations of the present invention will be apparent to those skilled in the art without departing from the spirit and scope of the present invention.

1. A decorative vapor deposition sheet comprising a cover resin layer and a metal vapor deposition layer, wherein
the cover resin layer has a thickness of 50 micrometers or greater,
the metal vapor deposition layer exhibits a granular structure,
a breaking elongation of the decorative vapor deposition sheet at 20° C. is 120% or greater, and
a breaking elongation of the decorative vapor deposition sheet at 160° C. is 350% or greater.

2. The decorative vapor deposition sheet according to claim 1, wherein the metal vapor deposition layer exhibits a discontinuous configuration partially or entirely in the layer in the cross-sectional portion in the thickness direction.

3. The decorative vapor deposition sheet according to claim 1, wherein a surface resistance value of the metal vapor deposition layer is 8.0×10¹⁰ Ω/□.

4. The decorative vapor deposition sheet according to claim 1, wherein an optical density of the metal vapor deposition layer is from 1.0 to 1.9.

5. The decorative vapor deposition sheet according to claim 1, wherein the cover resin layer comprises at least one selected from urethane, polyvinylidene fluoride, and (meth)acryl.

6. The decorative vapor deposition sheet according to claim 1, wherein the metal vapor deposition layer comprises at least one selected from indium and tin.

7. The decorative vapor deposition sheet according to claim 1, wherein an adhesive layer is disposed under the metal vapor deposition layer disposed under the cover resin layer.

8. The decorative vapor deposition sheet according to claim 1, which is used for a vacuum forming.

9. An article comprising the decorative vapor deposition sheet according to claim 1, wherein the decorative vapor deposition sheet is adhered to a substrate.

10. The article according to claim 9, which has a three-dimensional shape.

11. A method of producing an article having a three-dimensional shape, the method comprising vacuum-forming after applying the decorative vapor deposition sheet according to claim 1 to a substrate.
